(19) United States
(12) Patent Application Publication
(10) Pub. No.: US 2002/0037649 A1
(43) Pub. Date: Mar. 28, 2002

(54) Method for carrying out planarization processing

(75) Inventors: Katsuyoshi Shingu, Osaka (JP); Futoshi Ohtsuka, Osaka (JP)

Correspondence Address: GREENBLUM & BERNSTEIN, 1941 ROLAND CLARKE PLACE, RESTON, VA, 20191

(73) Assignee: MATSUSHITA ELECTRIC INDUSTRIAL CO., LTD.

(21) Appl. No.: 09/735,662

(22) Filed: Dec. 14, 2000

(30) Foreign Application Priority Data
Dec. 15, 1999 (JP) 11-355899

(51) Int. Cl. H01L 21/302; H01L 21/461

(52) U.S. Cl. 438/692

(57) ABSTRACT

There is provided a planarization process wherein a workpiece is polished uniformly.

When planarizing a surface to be processed of a workpiece by polishing the surface with a polishing pad, planarization is carried out by (a) disposing the polishing pad above the surface to be processed, so that a part of the surface to be processed is exposed out of the shadow of the polishing pad; (b) contacting the surface with the polishing pad so as to generate a pressure therebetween; and (c) oscillating the polishing pad while rotating the workpiece around its center axis as a rotation axis so as to polish the surface, respectively at two or more different positions on the surface to be processed, wherein the residence time of the polishing pad at each position is changed so as to make a processed amount of the surface at each position desired.

### CROSS-REFERENCE TO RELATED APPLICATION

The present application claims a priority under 35 U.S.C. §119 to Japanese Patent Application No. Hei11-355899, filed on Dec. 15, 1999, entitled “METHOD FOR CARRYING OUT PLANARIZATION PROCESSING.” The contents of that application are incorporated herein by reference in their entirety.

### FIELD OF THE INVENTION

The present invention relates to a method for planarizing a surface to be processed of a workpiece by polishing the surface. Particularly, the present invention relates to a planarization method which is suitable for planarizing a surface on which a wiring is formed or a surface of an insulating material layer as formed on a wiring in a process for the wiring formation on a surface of a semiconductor device as a workpiece.

### RELATED ART

Recently, a planarization method of polishing a surface to be processed of a workpiece so as to planarize the surface has been applied to various fields. A planarization method in a wiring process for a semiconductor device is one example thereof.

A wiring process for the semiconductor device is carried out as follows:

A wiring of an electrically conductive material such as aluminum is formed on a semiconductor substrate;

An inter-layer dielectric film is layered on the substrate having the wiring; and

The inter-layer dielectric film is polished so as to be planarized. The planarization of inter-layer dielectric film is necessary for forming a desired circuit pattern in a photolithography process. When the surface is uneven and difference in level is large, a part which is out of focus exits in a resist. Consequently, there exists a problem that the desired pattern cannot be formed.

When a wiring is further formed on an uneven surface of an inter-layer dielectric film, the thickness of the wiring material layer is thin at the edge of a step, and the layer is broken which results in breaking of the wire in the worst case. Further, there is another problem that when a wiring pattern is formed on an uneven surface of an inter-layer dielectric film, it may be difficult to etch the wiring material at the edge of a step, which results in a short circuit in the worst case.

In order to avoid these problems, the inter-layer dielectric film is planarized, for example, by using an etchback method, or a fluidization method in which SOG (Spin on Glass) or reflow is coated and then heated. However, the relevancy of the etchback method or the fluidization method depends on the sort of the insulating film. Further, although they can realize local planarization, they cannot realize global planarization.

Recently, the above conventional methods for carrying out the planarization have been replaced with a polishing method, particularly, chemical-mechanical polishing (CMP) which involves a chemical reaction of an inter-layer dielectric film with a polishing agent. The entire surface of the inter-layer dielectric film can be planarized very well by the CMP.

In a process for producing a semiconductor device, another wiring process is carried out as follow:

Trenches are provided on a surface of semiconductor substrate;

A film of an electrically conductive material is formed on the surface of the semiconductor substrate such that the electrically conductive material fills the trenches; and thereafter

The top surface of film of the electrically conductive material is planarized. The planarization is carried out so that the top surfaces of electrically conductive materials in the trenches are flush with the top surface of the substrate in order to insure that the electrically conductive materials in the adjacent trenches are insulated from each other. In this process, a polishing method, particularly the CMP is adopted as a planarization method.

One example of an apparatus for polishing a surface to be processed having a fine unevenness (or irregularities), such as a semiconductor device is disclosed in Japanese Patent Kokai (Laid-Open) Publication No. 201788/95. A method of using the apparatus as disclosed in the Kokai Publication No. 201788/95 will be explained with reference to FIG. 8. First, a disc-shaped workpiece (5) is fixed on a rotatable table (6) with a surface (5a) to be processed directed upward. Then, a disc-shaped polishing pad (1) is mounted on a rotatable holder (3) for the polishing pad. A surface of the polishing pad holder (3), on which the polishing pad (1) is to be mounted, is made of an elastic material (2).

The polishing pad (1) and the surface (5a) to be processed are disposed with a space therebetween, while a rotation axis of the former is away from that of the latter. A polishing slurry is, if necessary, fed between the polishing pad (1) and the surface (5a) to be processed; and the polishing pad (1) and the workpiece (5) are rotated while the polishing pad (1) is reciprocated in a radial direction of the surface (5a) to be processed. Thereafter, a gas is fed into the polishing pad holder (3); the pressure of this gas is transferred to the polishing pad (1) through the elastic member (2), and thereby the polishing pad (1) is pressed against the surface (5a) to be processed in a perpendicular direction, so that polishing is started. After polishing is carried out for a predetermined time, the internal pressure in the polishing pad holder (3) is released, and thus polishing the workpiece (5) is finished. Since the rotation axis of the polishing pad (1) can be shifted in a horizontal direction, the distance between the axis of the workpiece (5) and the axis of the polishing pad (1) can be changed, and thereby both a center area of the surface (5a) to be processed and an peripheral area thereof can be polished.

In the apparatus as shown in FIG. 8, the polishing pad is disposed on the surface to be processed so that a diameter of the polishing pad overlaps at least one radius of the surface to be processed and the diameter of the polishing pad includes the radius of the surface to be processed. The ratio of the rotation number of the polishing pad (1) to that of the workpiece (5) is set on the basis of the results which have been obtained by preliminary trials of processing, so that a processed amount of the workpiece is even over the entire surface to be processed.

According to the apparatus, since the workpiece (5) and the polishing pad (1) are rotated with their axes being away from each other, a relative motion is caused between the workpiece and the polishing pad, so that the polishing pad (1) polishes the entire surface (5a) to be processed. The polishing pad (1) is pressed against the surface (5a) to be processed through the polishing slurry under a constant pressure. Thus, even when the workpiece is warped, a relatively uniform planarization processing can be carried out.

It is noted that a polishing time is generally determined as follows:

Firstly, a thickness of a workpiece is measured at several points, for example, 5 or 9 points;

An amount to be removed by polishing (i.e. an amount to be processed) is determined from an average value of the thicknesses;

A polishing rate is determined. The polishing rate is generally determined experimentally, since the polishing rate depends upon the sort of the workpiece, the sort (for example, material) and the area of the polishing pad; the relative velocity between the polishing pad and the workpiece; the pressure between the polishing pad and the workpiece; the sort of the polishing slurry and the like; and

The polishing time is calculated by dividing the amount to be removed by the polishing rate.

### PROBLEMS SOLVED BY THE INVENTION

The apparatus as shown in FIG. 8 is designed so that it is not tend to be affected by the warpage of the surface to be processed; however, a further improvement is required. For example, when there exists in the surface to be processed a waviness having a cycle of several centimeters and an amplitude of several micrometers as well as simple warpage, and/or when there exists an unevenness on an abrasive surface of the polishing pad, a polishing rate of a part or a whole of the surface to be processed is not still controlled by the general abrasion rules, i.e. Preston equation, even if the surface to be processed is polished with the above-mentioned apparatus. Consequently, there exists a problem that a processing accuracy is deteriorated. A similar problem is also caused in chemical-mechanical polishing (CMP) or mechano-chemical polishing (MCP), in which a component of a polishing slurry reacts with a workpiece on the surface to be processed.

Herein, the “processing accuracy” is represented by the difference between an aimed processed amount and an actual processed amount. The larger the difference is, the worse the processing accuracy is. The processed amount is commonly represented by a thickness of a workpiece (or a film) which was removed (or abraded) during planarization processing (or polishing).

Further, ups and downs (or undulations) may exist on the surface to be processed because of unevenness in a thickness of an inter-layer dielectric film formed on a semiconductor substrate, i.e. unevenness in a distance between a top surface of the substrate and a top surface of the film. Such ups and downs generally have a cycle (which is a length from a summit to an adjacent summit) of several centimeters and a height in the range of several hundreds of nanometers to several micrometers. When the surface having such ups and downs is polished, polishing tends to proceed with the ups and down remaining. Therefore, it is generally difficult to achieve sufficient planarization over a whole of the surface.

The present invention has been accomplished in the light of the circumstances as described above, of which object is to provide a planarization method according to which an entire surface to be processed of a workpiece can be polished more uniformly.

### SUMMARY OF THE INVENTION

In order to solve the above-mentioned problems, the present invention provides a method for carrying out a planarization processing comprising polishing a surface to be processed of a workpiece with a polishing pad so as to planarize the surface to be processed, which comprises:

(a) disposing the polishing pad above the surface to be processed, so that a part of the surface to be processed is exposed (or protruded) out of the shadow of the polishing pad;

(b) contacting the surface to be processed with the polishing pad so as to generate a pressure therebetween; and

(c) oscillating the polishing pad while rotating the workpiece around its center axis as a rotation axis so as to polish the surface to be processed of the workpiece, respectively at two or more different positions on the surface to be processed, in which method a processed amount at one position is different from that at other one or more positions on the surface to be processed.

In the process (a) in which the polishing pad is disposed, the polishing pad is disposed at two or more different positions on the surface to be processed. This is carried out by selecting a certain point as a reference point of the polishing pad which has an abrasive surface (for example, said certain point is the center of an abrasive surface), and disposing the reference point at at least two different positions on the surface to be processed.

The “two or more different positions” are referred to as two or more different positions when considering a state in which the workpiece is static. In the process (c) in which the surface to be processed is polished, the reference point of the polishing pad is displaced relative to a position on the surface to be processed due to the rotation of the workpiece and the oscillation of the polishing pad; however, such displacement does not correspond to disposing the polishing pad at two or more different positions on the surface to be processed.

The expression “a part of the surface to be processed is exposed out of the shadow of the polishing pad” means that the polishing pad is disposed above the surface to be processed so that a part of the surface to be processed does not overlap the polishing pad (i.e. so that the polishing pad does not lie above at least a part of the surface to be processed) when considering a state in which both of the workpiece and the polishing pad are static, i.e. in a state of the process (a) in which the polishing pad is disposed.

Therefore, in the method of the present invention, a polishing pad of which abrasive area is smaller than an area of the surface to be processed of the workpiece is preferably used. When the workpiece and the polishing pad are disc-shaped, the diameter of the polishing pad is preferably smaller than that of the workpiece.

The expression “oscillating a polishing pad” means that the polishing pad is linearly reciprocated in a direction parallel to the surface to be processed (generally in a horizontal direction).

In the method of the present invention for the planarization, since the movement of the polishing pad from one position to the next position is generally not continuous, a difference in a level (or a step) is prone to be formed between abraded areas each of which is polished with the polishing pad disposed at each position. In order to remove this difference in the level, the polishing pad is oscillated. The polishing pad is preferably oscillated in a direction along which the polishing pad is shifted from a certain position to the next position. For example, when the workpiece is disc-shaped, the polishing pad may be shifted successively in a radial direction of the workpiece, and oscillated in the radial direction of the workpiece. When the workpiece is rectangular-shape, the polishing pad may be shifted successively in a diagonal direction of the rectangular workpiece, and oscillated in the diagonal direction of the workpiece.

In the method of the present invention for the planarization, the workpiece is rotated around its center axis as a rotation axis. The “center axis” of the workpiece is an axis which is vertical or perpendicular to the surface to be processed of the workpiece and passes through the center of the surface. The rotation of the workpiece and the oscillation of the polishing pad cause a relative motion between the polishing pad and the workpiece, and thereby the surface to be processed is polished.

Further, the relative velocity between the polishing pad and the workpiece can be increased by rotating the polishing pad around its center axis as a rotation axis. The “center axis” of the polishing pad is an axis which is vertical or perpendicular to the abrasive surface of the polishing pad and passes through the center of the abrasive surface.

A period (or time) during which the surface to be processed is polished by the polishing pad which is in contact with the surface, i.e. a period during which the process (c) is carried out, is referred to as “a residence time of the polishing pad” herein.

As described in the above, the method of the present invention is characterized in that the processed amount at one position is different from that at other one or more positions on the surface to be processed. The “processed amount” means a “stock removal” of the surface to be processed and corresponds to a difference between thicknesses of the workpiece before and after the planarization processing in the present invention (or a difference in distances between a top surface of a film to be planarized and a top surface of a substrate before and after the planarization processing). The expression “a processed amount at one position is different from that at other one or more positions on the surface to be processed” means that it does not occur that processed amounts at all positions on the surface to be processed are the same each other. With this feature, the processed amount can be larger or smaller as desired depending on the position on the surface to be processed, and thereby the thickness of the workpiece is more even and the planarity of the surface to be processed is further improved.

When processed amounts at “M” positions (wherein “M” is 3 or an integer of more than 3) are compared with each other, for example, the following are included in the case where the processed amount at one position is different from that at other one or more positions on the surface to be processed:

A processed amount at certain one position is different from processed amounts at other “M−1 (M minus one)” positions all of which amounts are the same;

Each of processed amounts at “N” positions (wherein “N” is 2 or an integer of more than 2 and less than “M”) is “H” and each of processed amounts at “M−N (M minus N)” positions is “H′” (wherein “H” is not equal “H′”);

Each of processed amounts at “L” positions (wherein “L” is 2 or an integer of more than 2 and less than “M”) is “J” and none of processed amounts at “M−L (M minus L)” positions is “J”; and

A processed amount at each position is different from each other.

Further, the case where the processed amount at one position is different from that at other one or more positions on the surface to be processed includes a case where there is at least one pair of the processed amounts which are different from each other in all pairs randomly selected from the processed amounts which are measured at a plurality of positions.

“One position” is a single position selected on the surface to be processed and may be selected arbitrarily. “One position” may be, for example, conveniently any one of the positions where the reference point of the polishing pad is located. Therefore, the method for the planarization of the present invention includes an embodiment in which the processed amount at a certain position where the reference point of the polishing pad is disposed is different from a processed amount at other one or more positions where the reference position of the polishing pad is disposed.

Thus, according to the method for the planarization of the present invention, when the thickness of an inter-layer dielectric film formed on a semiconductor substrate is uneven (i.e. the distance between a top surface of the inter-layer dielectric film and a top surface of the semiconductor substrate is uneven), it is possible to make the thickness even at the end of the planarization processing by making the processed amount increased at the position where the thickness is thicker. If a plurality of films are formed on the substrate, the total thickness which is a sum of the thickness of each film can be even.

The above feature as to the processed amount is realized by an embodiment in which, in a set of the residence times of the polishing pad at respective positions, one residence time is different from other one or more residence times. The “set of the residence times of the polishing pad at respective positions” is a set of elements of “t1” to “tm” (wherein “m” is 2 or an integer of more than 2) which are the residence times of the polishing pad which is disposed at different “m” positions, for example, positions “P1” to “Pm” respectively on the surface to be processed. By making one residence time different from other one or more residence times in the set, it is possible to make the processed amount desired at each position on the surface to be processed, and thereby a distribution of the processed amount over the surface can be as desired.

In order to obtain a desired distribution of the processed amount over the surface to be processed, it is necessary to determine the residence times of the polishing pad at the respective positions where the polishing pad should be disposed successively, depending on the positions where the polishing pad is disposed successively, the polishing rates at each positions on the surface to be processed when the polishing pad is disposed at the respective positions where the polishing pad should be disposed successively and so on. In a set of the residence times thus determined, one residence time is generally different from other one or more residence times. A processed amount at one certain position on the surface to be processed corresponds to a sum of products each of which is obtained by multiplying a polishing rate at the certain position by a residence time of the polishing pad when the polishing pad is disposed at the respective positions.

For example, a case is considered where the reference point of the polishing pad is disposed at a position “Pa” on the surface to be processed followed by polishing the surface, and then the reference point is shifted to other position “Pb” on the surface to be processed followed by polishing the surface. Depending on the manner in which the reference point of the polishing pad is shifted (for example, when “Pb” is close to “Pa”), wherever the polishing pad is disposed, a certain position “Za” on the surface to be processed is beneath the polishing pad (i.e. a part of the polishing pad exists on the position “Za”). In that case, the position “Za” on the surface to be processed is polished twice. Therefore, the processed amount at the position “Za” on the surface is a sum of a product of “Ma” and “ta”, i.e. “Ma×ta” and a product of “Mb” and “tb”, i.e. “Mb×tb” (that is “Ma×ta”+“Mb×tb”), wherein “Ma” is a polishing rate at the position “Za” on the surface when the polishing pad is disposed at the position “Pa”; “ta” is a residence time of the polishing pad at the position “Pa”; “Mb” is a polishing rate at the position “Za” on the surface when the polishing pad is disposed at the position “Pb”; and “tb” is a residence time of the polishing pad at the position “Pb.” In such a case, in order to make the processed amount at the position “Za” desired, the residence times “ta” and “tb” of the polishing pad are determined by solving simultaneous equations or calculated by using matrices, as described later.

As other example, there is a case where a position “Zc” on the surface to be processed is beneath the polishing pad only when the reference point of the polishing pad is disposed at the position “Pc” on the surface and is not beneath the polishing pad which is disposed at other position “Pd” (for example, when the position “Pc” is far from the position “Pd”). In such a case, the processed amount at the position “Zc” on the surface is determined by the product of “Mc” and “tc”, i.e. “Mc×tc” wherein “Mc” is a polishing rate at the position “Zc” on the surface and “tc” is a residence time of the polishing pad when the polishing pad is disposed at the position “Pa”. Therefore, the processed amount at the position “Zc” on the surface can be a desired one by selecting the polishing rate “Mc” and/or the residence time “tc” of the polishing pad appropriately. In a case where there exist a plurality of positions like “Pc” on the surface to be processed, in one embodiment of the present invention, by making a polishing rate and/or a residence time at one position different from a polishing rate and/or a residence time at other one or more positions, the processed amount at the former position is different from the latter position(s) on the surface to be processed, and thereby, the surface can be planarized. In other embodiment of the method for the planarization of the present invention, for example, when a polishing rate is previously known, a residence time to be set is obtained by determining a desired processed amount.

The method for the planarization of present invention is suitable for polishing a workpiece which is disc-shaped using a polishing pad which is disc-shaped. In that case, the polishing pad is preferably shifted in a radial direction of the surface to be processed. More preferably, the center of the polishing pad is shifted from the center toward the periphery side of the surface to be processed in the radial direction of the surface, and thereby the polishing pad is disposed at two or more positions so that distances between the center axis of the workpiece and the center axis of the polishing pad upon being disposed at the positions are different from each other. Further more preferably, the center of the polishing pad is shifted by the same distance at each shift.

Herein, the polishing pad and the workpiece “which are substantially disc-shaped” include ones such as semiconductor wafers, which have an orientation flat so that an arc of a circle is cut away, as well as the one having a surface to be processed of which shape is completely circular. Furthermore, even if an article has a periphery which is not a smooth curve, it is considered that the article is substantially disc-shaped as long as the distances from the center of the article to the periphery are not largely different from each other. Thus, for example, a substantially disc-shaped workpiece or polishing pad includes one of which shape is an equilateral polygon having the number of the angular points of six or more.

Next, a manner to determine the residence time of the polishing pad at each position so that a distribution of the processed amounts on the surface to be processed is as desired will be explained concretely. The residence time is determined by calculating from the desired processed amount at each position on the surface to be processed and a polishing rate which has been measured at each position on the surface to be processed. The manner is explained in detail hereinafter.

First, according to the surface to be processed, polishing conditions such as an area and a sort (for example, a material) of the polishing pad, a condition of the oscillation of the polishing pad (for example, a width and a frequency of the oscillation), a rotation number of the workpiece, a pressure between the polishing pad and the workpiece, a sort of a polishing slurry, and a rotation number of the polishing pad when the polishing pad is rotated, as well as a plurality of the positions on the surface to be processed where the polishing pad is disposed and the residence times of the polishing pad (i.e. polishing times) at the positions are suitably selected. The polishing conditions may be, for example, ones which are adopted conventionally. Then, under the selected conditions, polishing is carried out at each position while the polishing pad is successively shifted; and the polishing rate of the surface to be processed at each position is measured.

The polishing rates are measured at the different “m” positions (“Z1” to “Zm”) on the surface to be processed, when the reference point of the polishing pad is disposed at the different “m” positions (“P1” to “Pm”) on the surface to be processed. The positions “Z1” to “Zm” may be the positions “P1” to “Pm” or may be different from the positions “P1” to “Pm.” When the polishing pad is disposed at certain one position and polishing is carried out, the polishing rates are measured at the “m” positions (“Z1” to “Zm”) on the surface to be processed. Therefore, the number of the polishing rates which are measured is “m×m.” When the polishing pad is disposed at said certain one position and polishing is carried out, all the “m” positions (“Z1” to “Zm”) are not always polished, and some unpolished positions may exist. The polishing rates at such unpolished positions are zero. The positions where the polishing rates are measured are preferably the positions “P1” to “Pm” where the polishing pad is disposed.

The polishing rate is a processed amount per unit time, generally per minute, which can be obtained by dividing “a change in the thickness of a workpiece or a film before and after polishing (i.e. a processed amount)” by “the polishing time”.

The polishing rates are determined by polishing one or several workpieces under the selected polishing conditions as described above which workpieces are selected from a group of the workpieces to be planarized which are included in the same lot.

A desired processed amount at each position on the surface to be processed is determined as follows:

Firstly, the thickness of the workpiece is measured at the “m” positions (“Z1” to “Zm”) where the polishing rate are to be measured. The thickness of the workpiece may be measured at one or more positions other than the positions “Z1” to “Zm.” For example, the thickness of the workpiece may be measured over the entire workpiece;

Then, an amount of the thickness at each position of “Z1” to “Zm” to be reduced for planarizing the surface to be processed is determined on the basis of the results of the thickness measurement. The amount of the thickness to be reduced corresponds to the desired processed amount. When the polishing rates of the surface to be processed are measured at the positions “P1” to “Pm” where the polishing pad is disposed as described in the above, the desired processed amounts at the positions “P1” to “Pm” are determined.

A processed amount at a certain position Z on the surface to be processed corresponds to a sum of the products each being obtained by multiplying a polishing rate at the position Z by a residence time of the polishing pad when the polishing pad is disposed at each position where the polishing pad should be disposed. Namely, when the reference point, for example, the center of the polishing pad is disposed at different “m” positions (“P1” to “Pm”) on the surface to be processed, the processed amount R at the position “Z” on the surface is expressed by the following equation (1):

$$R = {\sum }_{k = 1}^{m} {M}_{K} * {t}_{K} \qquad ( 1 )$$

In the equation (1), “Mk” represents a polishing rate at the position “Z” when the reference point of the polishing pad is disposed at the “k”th position “Pk” wherein “k” is an integer of 1 to m and polishing by the pad is carried out; and “tk” represents a residence time of the polishing pad when the reference point of the polishing pad is disposed at the “k”th position “Pk”. “Mk×tk” corresponds to a processed amount at the position “Z” when the reference point of the polishing pad is disposed at the “k”th position “Pk”.

In order to determine the residence times “t1” to “tm” of the polishing pad so that the distribution of the processed amounts on the surface to be processed is as desired, it is necessary to form equations which are similar to the equation (1) for “m” different positions on the surface to be processed; to substitute a desired processed amount at each position in each equation; and to solve m-element simultaneous linear equations. When the polishing rates are measured at the positions “Z1” to “Zm” on the surface to be processed, the following “m” equations (2):

$$Ri = {\sum }_{k = 1}^{m} {M}_{ik} * {t}_{k} \qquad ( 2 )$$

are formed. In the equation (2), “Ri” represents a processed amount at the position “Zi” on the surface to be processed wherein “i” is an integer of 1 to m; “Mik” represents a polishing rate at the position “Zi” (wherein “i” is an interger of 1 to m) when the reference point of the polishing pad is disposed at the “k”th position “Pk” (wherein “k” is an integer of 1 to m) and polishing by the pad is carried out; and “tk” represents a residence time of the polishing pad when the reference point of the polishing pad is disposed at the “k”th position “Pk”. The m-elements simultaneous linear equations are obtained by substituting a desired processed amount at the position “Zi” on the surface to be processed (wherein “i” is an integer of 1 to m) for “Ri” in each of the “m” equations (2). By solving these simultaneous linear equations, the residence times “t1” to “tm” of the polishing pad disposed at the positions “P1” to “Pm” are determined.

Such simultaneous equations are represented as “R=M×X” wherein “M” is an “m (rows)×m (columns)” matrix in which “mᵢₖ” corresponds to an element located in the “i”th row and the “k”th column; “X” is an “m (rows)×1 (column)” matrix of which elements are “t1” to “tm”; and “R” is an “m (rows)×1 (column)” matrix of which elements are “R1” to “Rm.” Therefore, when the matrix “X” is unknown, the matrix “X” is determined by the product of an inverse matrix “M⁻¹” of the matrix “M” and the matrix “R”, i.e. “R×M⁻¹.”

For example, when the center of the disc-shaped polishing pad is shifted “n” times (n is an integer of 1 or more) by the length “d” in a radial direction of the disc-shaped workpiece from the center to the periphery of the workpiece, the polishing rate is previously determined as an (n+1)×(n+1) matrix “A” of which an element “a_{ydxd}” located in the (y+1)th row and the (x+1)th column represents a polishing rate of the surface to be processed at the position which is “yd” (wherein “y” is an integer of 0 to n) apart from the center of the workpiece when the polishing pad is disposed at a position where the distance between the center of the polishing pad and the center of the workpiece is “xd” (wherein “x” is an integer of 0 to n). Herein, the positions where the polishing rates are measured are the same as positions each of which the polishing pad is disposed at.

The matrix “A” is represented, for example, as follows:

$$( \begin{matrix}{a}_{0 d0d} & {a}_{0 d1d} & {a}_{0 d2d} & 0 & 0 & 0 & 0 & 0 & 0 \\ {a}_{1 d0d} & {a}_{1 d1d} & {a}_{1 d2d} & {a}_{1 d3d} & 0 & 0 & 0 & 0 & 0 \\ {a}_{2 d0d} & {a}_{2 d1d} & {a}_{2 d2d} & {a}_{2 d3d} & {a}_{2 d4d} & 0 & 0 & 0 & 0 \\ 0 & {a}_{3 d1d} & {a}_{3 d2d} & {a}_{3 d3d} & {a}_{3 d4d} & {a}_{3 d5d} & 0 & 0 & 0 \\ 0 & 0 & & & ⋯ & & & 0 & 0 \\ 0 & 0 & 0 & & ⋯ & & & & 0 \\ 0 & 0 & 0 & & ⋯ & & & & \\ 0 & 0 & 0 & & ⋯ & & & & \\ 0 & 0 & 0 & 0 & ⋯ & & & & {a}_{ndnd}\end{matrix} ) = A$$

The matrix “A” represents the polishing rate at each position when the center axis of the disc-shaped polishing pad is shifted by the length “d” by “d” in the radial direction from the center axis of the disc-shaped workpiece. The row of the matrix “A” represents a polishing rate at a position of the surface to be processed which position is at a predetermined distance from the center axis of the workpiece, and the matrix “A” shows that the polishing rate at said position varies depending upon the position of the polishing pad. The column of the matrix “A” corresponds to a polishing rate at each position of the surface to be processed when the center axis of the polishing pad is disposed at a certain position. In the matrix “A”, the polishing rate is shown with “a_{ydxd}”; the subscript “xd” (wherein “x” is an integer, and “d” is a length of the polishing pad per one shift) corresponds to a distance between the center axis of the polishing pad and the center axis of the workpiece; the subscript “yd” (wherein “y” is an integer, and “d” is a length of the polishing pad per one shift) represents a position of the surface to be processed and corresponds to a distance between the center of the workpiece and said position of the surface to be processed.

For example, “a_{0d0d}” represents a polishing rate at the center of the surface to be processed when the center axis of the polishing pad overlaps the center axis of the workpiece, while “a_{3d2d}” represents a polishing rate of the surface to be processed at a position which is “3d” apart from the center of the workpiece when the center axis of the polishing pad is disposed “2d” apart from the center axis of the workpiece. Polishing is carried on till the center axis of the polishing pad passes over from the center axis to the periphery of the surface to be processed when the center axis of the polishing pad is shifted “d” by “d”. Therefore, “a_{ndnd}” shows the polishing rate at the outer edge of the surface to be processed when the center axis has substantially reached the outer edge of the surface to be processed. Accordingly, when the radial of the surface to be processed is assumed to be “r_{w}”, it substantially becomes r_{w}=n×d. In the matrix “A” as described above, the polishing pad disposed at certain one position polishes five positions on the surface to be processed simultaneously. At a position where the polishing rate is represented by “0”, the workpiece is not polished by the polishing pad disposed at said certain one position. The length over which the polishing pad is shifted one time, which is represented as “d” in the above, namely a migration length of the polishing pad when the center axis of the polishing pad is shifted from a certain position to the next position, is suitably selected according to the diameter of the polishing pad and the aimed processing.

The polishing rate of the workpiece at each position is thus determined under a predetermined condition, and then the residence time of the polishing pad at each position is determined so as to adjust the processed amount of the surface to be processed at each position to a predetermined one. Concretely, in a case where the predetermined amount to be processed at each position is arranged together as a matrix “H”, and each residence time of the polishing pad at each position is arranged together as a matrix “T”, since the relationship of “H=A·T” is maintained, the residence times can be determined by calculating the product of the inverse matrix A⁻¹ of the matrix “A” and the matrix “H”.

Namely, the residence time of the polishing pad at each time is determined by:

arranging the desired processed amounts of the workpiece in a matrix “H” having (n+1) rows and one column ((n+1)×1) in which an element located in the (y+1)th row represents as “h_{yd}” the desired processed amount at the position which is “yd” apart from the center of the workpiece wherein “y” is an integer of 0 to n; and

calculating the product of the inverse matrix “A⁻¹” of the matrix “A” and the matrix “H” to determine a matrix “T” having (n+1) rows and one column ((n+1)×1) in which an element located in the (x+1)th row represents as “t_{xd}” the residence time of the polishing pad at the position where the center of the polishing pad is “xd” apart from the center of the workpiece wherein “x” is an integer of 0 to n.

Concretely, the matrix “H” is represented as follows:

$$( \begin{matrix}{h}_{0 d} \\ {h}_{1 d} \\ {h}_{2 d} \\ {h}_{3 d} \\ ⋮ \\ {h}_{nd}\end{matrix} ) = H$$

Concretely, the residence time of the polishing pad at each position is represented as follows:

$$( \begin{matrix}{t}_{0 d} \\ {t}_{1 d} \\ {t}_{2 d} \\ {t}_{3 d} \\ ⋮ \\ {t}_{nd}\end{matrix} ) = T$$

In FIG. 6, a graph schematically shows as one example a distribution of a stock removal (i.e. processed amount) from the center “o” to “r” on the surface to be processed along a radial direction thereof when the center of the polishing pad is shifted “d” by “d” from the position where the distance “xd” between the center of the polishing pad and the center of the surface is “αd” to the position where “xd” is “βd”, wherein α is an integer of 0 or more and β is an integer of n or less. In FIG. 6, the stock removal is constant at each position from the center “o” to the position “r.” In FIG. 6, the parts “A”, “B”, “C”, “D” and “E” show the stock removals and areas which are polished off on the workpiece when the polishing pad is disposed at the positions where “xd” is “αd”, “(α+1)d”, “(α+2)d”, “(β−1)d” and “βd”, respectively. In FIG. 6, the stock removal at the position which is “z” apart from the center “o” of the workpiece corresponds to a sum of the polished amounts at the position “z” when the polishing pad is disposed at the positions where the distance “xd” between the center of the polishing pad and the center of the surface to be processed is respectively αd, (α+1)d and (α+2)d. It should be noted that FIG. 6 is shown as an example.

In the matrix “A”, all elements other than diagonal elements may be zero in some cases. In other words, there may be a case where each of the different “m” positions (“Z1” to “Zm”) on the surface to be processed is polished only once when the polishing pad is disposed at certain one position and each position is not polished when the polishing pad is disposed at other positions rather than said certain one position. Particularly in such a case, a distribution of the processed amount on the surface to be processed can be a desired one by changing a polishing rate at at least one position on the surface.

“Changing a polishing rate at at least one position on the surface to be processed” means after previously obtaining the polishing rate at each position on the surface to be processed under the predetermined polishing conditions as described above, changing at least one previously obtained polishing rate.

Concretely, the polishing rate at a certain position is changed by changing the rotation number of the polishing pad at the certain position when the polishing pad is rotated around its center axis as a rotation axis. The polishing rate increases when the rotation number of the polishing pad is increased from the rotation number upon the determination of the polishing rate. The polishing rate decreases when the rotation number of the polishing pad decreases from the rotation number upon the determination of the polishing rate. Changing the rotation number of the polishing pad at at least one position generally makes the rotation number thus changed at said position different from the rotation numbers at at least one other position. The polishing rate may be changed by other conventional methods. When the polishing rate (i.e. the rotation number of the polishing pad) is changed at at least one position, the residence time of the polishing pad at each position may be the same, or the residence time of the polishing pad at at least one position may be different from that at at least one other position.

By applying the method for the planarization of the present invention, it is possible to make the processed amount substantially uniform over the entire surface to be processed, when the thickness of the workpiece is uniform but the polishing rate of the workpiece is not constant over the entire surface to be processed; namely, it is possible to carry out the planarization processing so that the distribution of the processed amount of the surface to be processed can be very narrow.

### BRIEF DESCRIPTION OF THE DRAWINGS

FIG. 1 is a schematic sectional view illustrating an embodiment of a polishing tool for carrying out the method for the planarization processing of the present invention;

Each of FIGS. 2A to 2D is a schematic sectional view illustrating a process of the method for the planarization processing of the present invention;

FIG. 3 is a schematic sectional view illustrating an embodiment of a polishing tool which is included in an apparatus for carrying out the planarization processing of the present invention;

FIG. 4 is a schematic plan view illustrating an embodiment of a polishing pad for carrying out the method for the planarization processing of the present invention;

FIG. 5 is a schematic sectional view illustrating an embodiment of an apparatus for carrying out the method for the planarization processing of the present invention;

FIG. 6 is a graph which schematically shows a distribution of stock removal, which is obtained by carrying out the method for the planarization processing of the present invention;

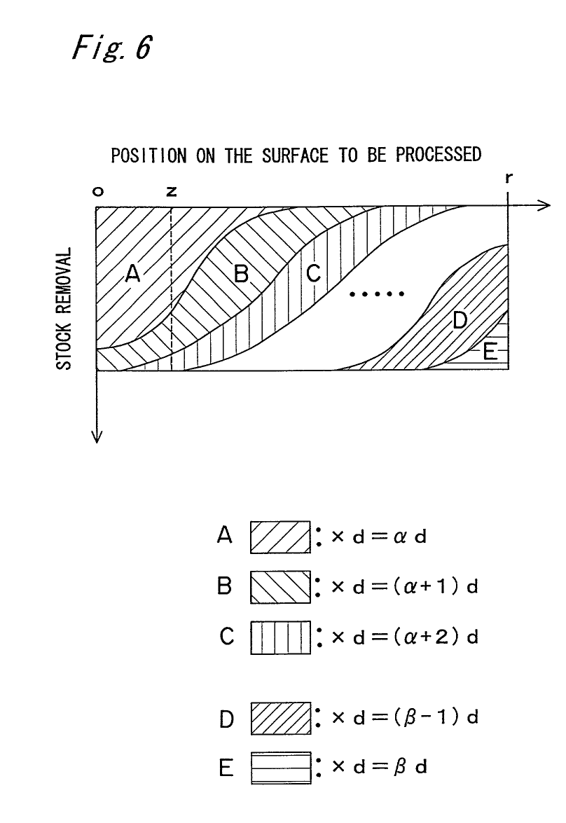

FIG. 7A is a schematic sectional view illustrating a semiconductor device before carrying out the planarization processing, and FIG. 7B is a schematic sectional view illustrating the semiconductor device after carrying out the planarization processing; and

FIG. 8 is a schematic sectional view illustrating the prior art method for carrying out the planarization processing.

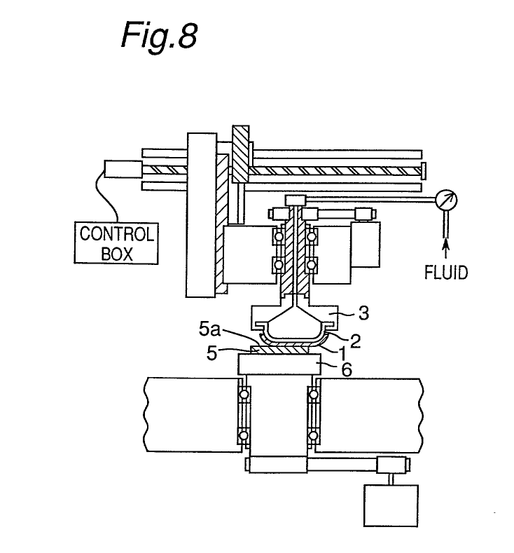

### DESCRIPTION OF THE PREFERRED EMBODIMENTS

Hereinafter, an embodiment in which the present invention is carried out will be explained. In the method for the planarization processing of the present invention, the sort of the workpiece or the polishing pad is not particularly limited. The present invention is preferably applied to a process for producing a semiconductor device for forming a semiconductor chip. Thus, for the purpose of the convenience of explanations, a concrete embodiment for carrying out the present invention will be described with exemplifying a method for planarizing a semiconductor device which is substantially disc-shaped.

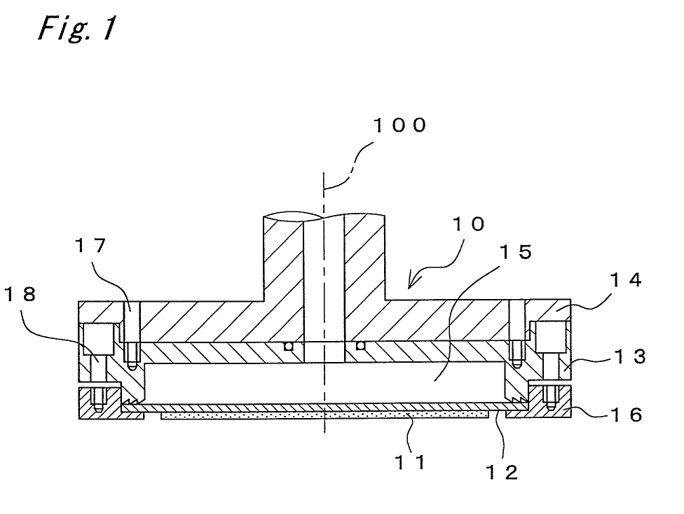

FIG. 1 is a sectional view in the direction of the thickness of a workpiece, which schematically illustrates a polishing tool used in the present invention. As to the polishing tool (10) as shown in FIG. 1, an elastic member (12) such as an elastic sheet is mounted on a polishing pad holder (13), and a substantially disc-shaped polishing pad (11) is mounted on the polishing pad holder (13) by being disposed on the elastic member (12). In the polishing tool (10), a space (15) in which fluid is injected is formed adjacent to the elastic member (12). The polishing pad holder (13) is mounted on a rotation head (14). The rotation head (14) is connected to a proper driving means so that it can rotate around a center axis (100) of the polishing pad (11) as a rotation axis which is a perpendicular axis through its center, and it can oscillate in a horizontal direction as shown in FIG. 1.

In the polishing tool (10), the elastic member (12) is fixed by being sandwiched between a pressing ring (16) and the polishing holder (13). In the embodiment as shown, the pressing plate (16) is fixed the polishing holder (13) by screws (not shown) passing through threaded holes (18). The polishing holder (13) is fixed to the rotation head (14) by screws (not shown passing through threaded holes (17).

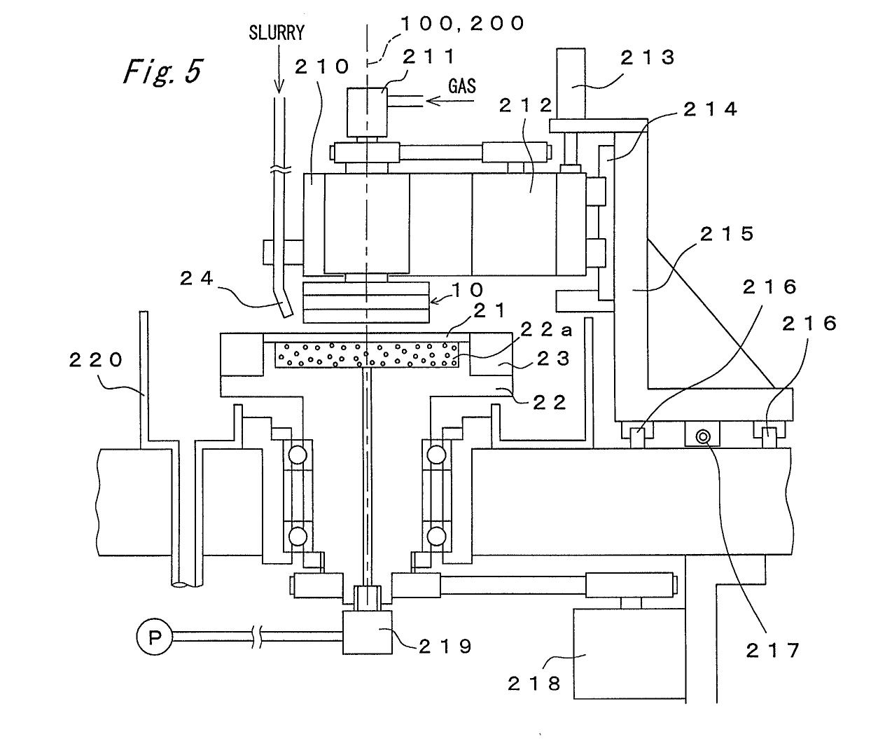

The polishing tool as shown in FIG. 1 is incorporated in a polishing apparatus as shown in FIG. 5 when it is used. In the polishing apparatus shown in FIG. 5, reference numeral 210 indicates a block; reference numeral 211 indicates a rotary joint; reference numeral 212 indicates a motor; reference numeral 213 indicates an air cylinder; reference numeral 214 indicates a linear motion guide rail; reference numeral 215 indicates a sliding table; reference numeral 216 indicates a linear motion guide rail; reference numeral 217 indicates a ball screw; reference numeral 218 indicates a motor; reference numeral 219 indicates a rotary joint; reference numeral 220 indicates a waste liquid receiver; reference numeral 21 indicates a workpiece; reference numeral 22 indicates a platen; reference numeral 22a indicates a suction plate; reference numeral 23 indicates a retainer ring; and reference numeral 24 indicates a slurry feeder.

The polishing tool (10) is attached to the block (210). The block (210) slides on the linear motion guide rail (214) which is provided on the sliding table (215) and extends up and down, and thereby the polishing tool (10) is moved up and down. The up and down motion of the sliding table (215) is controlled by the air cylinder (213). The sliding table (215) slides on the linear motion guide rails (216) extending in the direction which is perpendicular to the plane of the drawing sheet. An AC servomotor (not shown) directly connected to the ball screw (217) locates the sliding table (215) and controls the speed of the sliding table (215) to reciprocate the slide table (215), and thereby, the polishing tool (10) is oscillated. The polishing tool (10) is also rotated around the center axis (100) as a rotation axis by the rotation of the motor (212).

The workpiece (21) is fixed to the platen (22) through the suction plate (22a) by evacuation. The workpiece (21) can be rotated by the rotation of the motor (218).

A polishing slurry is supplied onto the workpiece (21) from the slurry feeder (24). Spent slurry exits the polishing apparatus through the waste liquid receiver (220).

FIG. 2 illustrates parts of the processes of the method for carrying out the planarization working of the present invention. FIG. 2A illustrates a state in which: the polishing pad (11) and the workpiece (21) are disposed so that the center axis (100) of the polishing pad (11) and the center axis (200) of the workpiece (21) overlap with each other; and the polishing pad (11) and the workpiece (21) are rotated around their center axes (100, 200) thereof as a rotation axis respectively, while the polishing pad (11) is oscillated in the radial direction of the workpiece (21) so as to abrade the surface (21a) to be worked. The polishing pad (11) is rotated with the rotation of the polishing tool (10), while the workpiece (21) is rotated with the rotation of a rotating table (22) for fixing the workpiece (21). In the embodiment as shown in FIG. 2, the diameter of the polishing pad (11) is smaller than that of the surface (21a) to be worked, and consequently a part of the surface (21a) to be worked with which part the polishing pad (11) is not in contact is exposed. During abrasion, the polishing pad (11) is pressed against the surface (21a) to be worked by the pressure of a gas injected in the space (15) in the polishing pad holder (13). The polishing slurry (25) is fed between the polishing pad (11) and the surface (21a) to be worked from the polishing slurry feeder (24).

FIG. 2B illustrates a state in which after the polishing process as shown in FIG. 2A is finished, the rotational motion of the polishing tool (10) is stopped; the pressure of the gas in the space (15) is released; and the rotation axis (100) of the polishing tool is shifted by the length “d” toward the periphery in the radial direction of the surface to be processed, and thereby the position of the polishing pad (11) is changed. Even at this position of the polishing pad (11), a part of the surface (21a) to be processed is exposed from the shadow of the polishing pad (11). FIG. 2C illustrates a state in which the polishing slurry (25) is fed between the polishing pad (11) and the surface (21a) to be processed from the polishing slurry feeder (24), and at the same time the oscillation of the polishing tool (10) is started.

FIG. 2D illustrates a state in which: the gas is injected in the space (15) in the polishing pad holder (13); the polishing pad (11) is pressed against the surface (21a) to be processed with the pressure of the gas, and the at the same time the polishing pad (11) is rotated around its center axis (100) as a rotation axis while it is oscillated so as to carrying out polishing.

It is noted that, in FIGS. 2B to 2D, the workpiece (21) is maintained in a state in which the workpiece (21) is rotated around its center axis (200) as a rotation axis, which is a perpendicular axis passing through the center of the workpiece (21).

After polishing as shown in FIG. 2D is finished, the rotation axis of the polishing tool is further shifted to the outer side of the surface to be processed in the radial direction thereof as shown in FIG. 2B, and thus the position of the polishing pad (11) is changed, and then the procedures as shown in FIGS. 2C and 2D are repeated. When the procedures as shown in FIGS. 2B to 2D are repeated till the center of the rotation of the polishing tool reaches the peripheral portion of the surface to be processed, the entire surface to be processed can be worked.

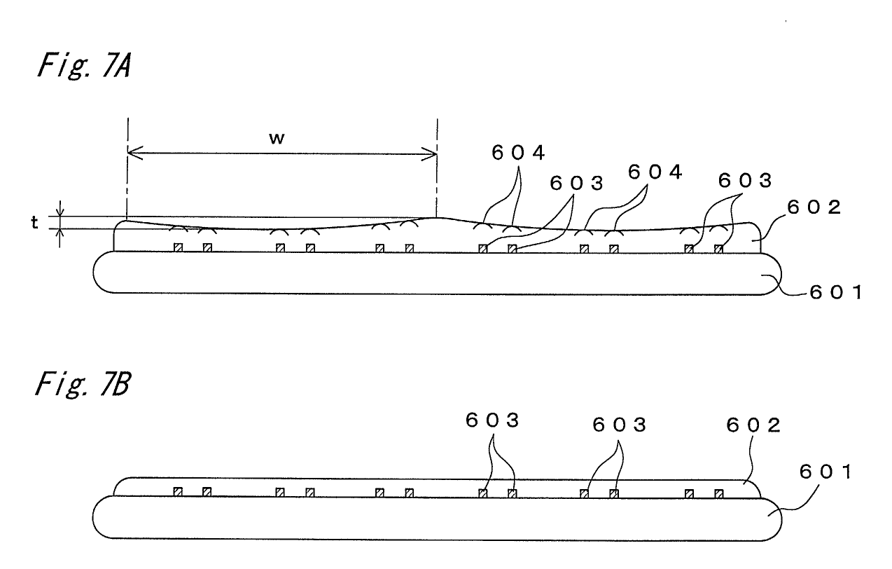

When the workpiece (21) is a semiconductor wafer (601) on which wirings (603) and a film (602) of an insulating material or the like are formed as shown in FIG. 7A, undulations (or ups and downs) of which cycles “W” are several centimeters and of which amplitudes “t” are in the range of several tens of nanometers to several micrometers, are generally formed on the surface to be processed of the wafer because the thickness of the film is not constant. The features of the undulations depend upon the sort of the material of the film and the like. In a process for producing the semiconductor device, such undulations should be removed as well as fine irregularities (604) which are formed during the film formation, so that the surface to be processed is overall planarized and the thickness of the film (602) is even as shown in FIG. 7B.

Therefore, it is necessary that the size of the polishing pad (11), the shift length “d” of the polishing pad (11) per one time and the like should be properly selected according to the features of the undulations of the workpiece (21).

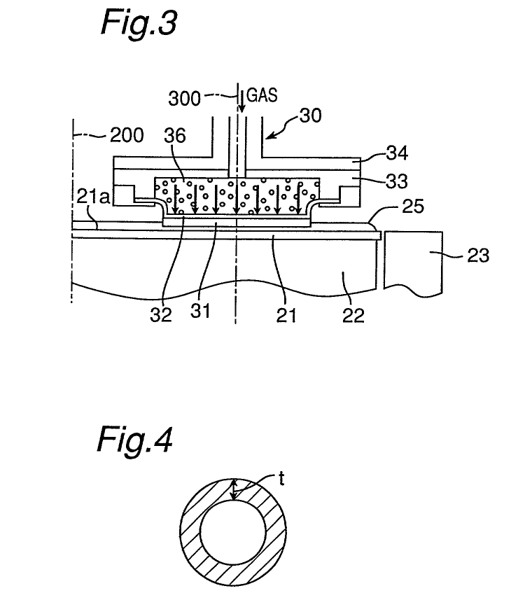

For example, when a disc-shaped semiconductor device is subjected to the planarization processing, it is preferred that, regarding each of the undulations formed in the semiconductor device to be processed, cycles thereof (which is a length between adjacent summits of the undulations) are measured so as to determine the minimum cycle among them, and that a disc-shaped polishing pad having a diameter smaller than the minimum cycle is selected. Alternatively, a ring-shaped polishing pad of which the ring width “t” is smaller than the minimum cycle of the undulation as shown in FIG. 4 may be used.

In the present invention, as shown in FIG. 2B, since polishing is interrupted so as to shift the center axis (100) of the polishing pad (11) by the length “d” after polishing at a certain position is finished (i.e. since the polishing pad (11) is not continuously shifted), a difference in level is prone to occur between polished areas which are formed with the polishing pad disposed at adjacent positions. In order to remove this difference in level, during polishing, the polishing pad (11) is oscillated in the radial direction of the workpiece (21) as shown in FIG. 2.

Furthermore, as shown in FIG. 2C, the oscillation of the polishing pad may be started after the polishing pad is shifted and before the polishing pad is pressed against the surface to be processed. When the polishing pad is previously oscillated before polishing while controlling the width and the frequency of the oscillation, the polishing pad can be surely oscillated on polishing with a predetermined width and frequency; however, the time at which the oscillation is started is not limited thereto. For example, starting the oscillation may be simultaneous with pressing the polishing pad against the surface to be processed.

As shown in FIGS. 2A and 2D, in addition to the oscillation of the polishing pad, the polishing pad may be rotated around its center axis as a rotation axis (i.e. rotated on its own axis). When the polishing pad is subjected to the rotational motion, the polishing rate of the surface to be processed is increased, and thus the planarization processing can be carried out in a shorter time. It is noted that such rotational motion is optional.

The sort of the polishing pad, the area of the polishing pad, the conditions of the oscillation of the polishing pad, and the sort of the polishing slurry, and if necessary, the conditions of the rotational motion of the polishing pad are thus determined according to the surface to be processed of the workpiece, and further, the pressure which is exerted between the polishing pad and the surface to be processed, the rotating speed of the workpiece, and the shift length “d” per time of the polishing pad are suitably established, and then the residence time of the polishing pad at each position is determined. Concretely, as mentioned above, the residence time at each position is determined as a matrix “T” which is calculated from the polishing rate (the matrix “A”) at each position under the predetermined conditions and the predetermined amount (the matrix “H”) to be processed at each position.

The polishing rate at each position of the surface to be processed depends upon the area of a polishing pad; the shift length “d” of the polishing pad per time; the pressure between the surface to be processed and the polishing pad; the sort of the polishing pad; the conditions of the oscillation of the polishing pad; the rotation number of the workpiece; the rotation number of the polishing pad when it is rotated; the sort of the polishing slurry; whether a chemical reaction is involved or not on polishing; and the like. Therefore, due to such polishing rate, the residence time of the polishing pad at each position on the surface to be processed is different.

In FIG. 2D, the gas is injected into the space (15) in the polishing pad holder (13), the pressure of the gas is transferred to the polishing pad through the elastic member (12), and thereby the polishing pad (11) is pressed against the surface (21a) to be processed so that the pressure is generated between the surface (21a) and the polishing pad (11). The gas is preferably used because it is easy to handle with a gas, and because even if the gas were leaked, the semiconductor device would not be contaminated. The gas may be air, N₂ or the like. Furthermore, in place of the gas, other fluid such as a liquid may be injected into the polishing pad holder, wherein it is preferred to use pure water from the viewpoint of avoidance of contamination.

With respect to the polishing tool (10) as shown in FIG. 1, when the fluid is injected into a space (15) in a polishing pad holder (13), if a polishing pad (11) is protruded out of the periphery of the surface (21a) to be processed, the protruded area loses support by means of the surface (21a) to be processed, and thus such area is bagged downward and a larger pressure is applied to the periphery portion of the surface (21a). Consequently, in the vicinity of the periphery of the surface (21a) to be processed, excessive polishing is likely to be caused. As an example of means for preventing the excessive polishing, as shown in FIG. 2, there is a method in which a retainer ring (23) is provided around the periphery of the workpiece (21). The top surface of the retainer ring (23) is almost coplanar with the surface (21a) to be processed. Therefore, even when a part of the polishing pad (11) is protruded out of the surface (21a) to be processed, the retainer ring (23) supports the polishing pad (11) to prevent the excessive polishing in the vicinity of the periphery of the surface (21a). Such a retainer ring (23) preferably supports all the protruded area of the polishing pad, even when the polishing pad (11) is protruded at any degree. Therefore, it is preferred that the top surface of the retainer ring (23) has such a sufficiently large area as all the protruded area of the polishing pad (11) can be supported even when the protruded area is maximized.

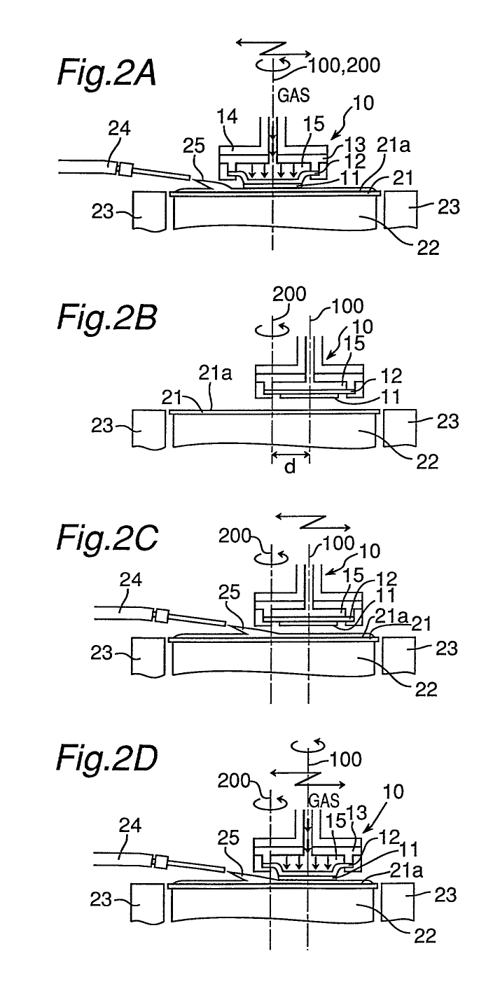

In order to prevent the excessive abrasion in the vicinity of the periphery of the surface (21a) to be processed, as shown in FIG. 3, a polishing tool (30) comprising an open-cell foam body (36) which is filled into a polishing pad holder (33), may be used. By means of this polishing tool (30), a fluid (such as a gas) is fed into the cells of the foam body (36), the pressure of the fluid is transferred to the polishing pad through the foam body (36) and an elastic member (32), and thereby the polishing pad (31) can be pressed against the surface (21a) to be processed.

Since the foam body (36) has a certain shape, the foam body (36) does not tend to expand partly. Therefore, even when the polishing pad (31) is disposed at the periphery area of the surface (21a) to be processed, and a part of the polishing pad (31) is protruded out of the periphery of the surface (21a) to be processed, a pressure as applied to the protruded portion of the polishing pad (31) is not remarkably increased as compared with a pressure acted on the other portion of the polishing pad.

Accordingly, the size of the retainer ring (23) for supporting the protruded portion of the polishing pad is miniaturized as far as a part of the protruded portion can be supported. Thus, by using the polishing tool as shown in FIG. 3, the retainer ring (23) can be smaller than that which is used with a polishing tool as shown in FIG. 1. The foam body (36) is preferably an urethane foam. As shown in FIG. 3, if necessary, the polishing pad holder (33) may be mounted on a rotation head (34) so that the polishing pad (31) can be subjected to a rotational motion around its center axis (300) as a rotation axis.

The method for the planarization processing of the present invention is carried out to planarize, for example, a workpiece which is produced by forming a wiring on a surface of a semiconductor wafer and coating the wafer with an inter-layer dielectric film, so that the surface of the inter-layer dielectric film is planarized. Specifically, the workpiece is such as one comprising: the semiconductor wafer of which diameter is in the range of 150 to 300 mm, the wiring which is formed of aluminum, and the inter-layer dielectric film which is about 1300 nm in thickness and made of P-TEOS, O₃-NSG, BPSG or the like. Such a workpiece generally has ups and downs having a cycle in the range of 50 to 200 mm and an amplitude in the range of 50 to 200 nm on the surface to be processed because the thickness of the inter-layer dielectric film is not even.

The planarization processing is carried out by polishing the surface to be processed with a polishing pad which is selected according to the sort of the film to be planarized and so on, while supplying a polishing slurry. For polishing the inter-layer dielectric film, a polishing pad of foamed polyurethane is preferably used.

The polishing pad preferably has a diameter which is smaller than the minimum cycle of the ups and downs formed on the surface to be processed. Therefore, the diameter of the polishing pad is preferably in the range of 50 to 200 mm.

When the polishing tool as shown in FIG. 1 is used, the elastic member is preferably a round sheet which is made of a neoprene rubber and has a thickness in the range of 0.5 to 4 mm. The elastic member is mounted on the polishing pad holder so that it forms a space, in which a fluid is filled, together with the polishing pad holder in the polishing tool. The elastic sheet is fixed to the polishing pad holder by, for example, being sandwiched between the polishing pad holder and a pressing ring. The polishing pad is attached to the surface of the elastic member with, for example, a double-faced silicone based adhesive tape.

Preferred polishing conditions in case where the aforementioned workpiece is polished by the method shown in FIG. 2 while using the aforementioned polishing tool, are described hereinafter.

The rotation number of the polishing pad is preferably in the range of 20 to 180 rpm, and the rotation number of the workpiece is preferably in the range of 60 to 360 rpm. The polishing pad is preferably oscillated with the width (which corresponds to a distance between the right-most and the left-most positions where the center of the polishing pad is disposed when it is oscillated as shown in FIG. 2A) in the range of 10 to 50 mm and the frequency in the range of 10 to 60 per minute.

The fluid which is supplied into the polishing tool is preferably compressed air. The supply of the fluid into the polishing tool preferably generates a pressure in the range of 5 kPa to 50 kPa between the abrasive surface of the polishing pad and the surface to be processed of the workpiece.

When an inter-layer dielectric film comprising Si and O is polished, the polishing slurry comprising silica or ceria microparticles as abrasive which are dispersed in an aqueous solution of NH₄OH or KOH is preferably used. Polishing slurry is preferably supplied at a rate in the range of 50 to 200 ml/min.

The shift length “d” per time of the polishing pad is preferably ⅕ to 1/20 of the radius of the workpiece. Therefore, the shift length “d” is preferably in the range of 5 to 20 mm for the aforementioned workpiece.

Under the aforementioned polishing conditions, the polishing rate of the workpiece is generally in the range of 50 to 300 nm/min. The workpiece is polished such that the processed amount (i.e. removed amount) of the inter-layer dielectric film is for example 1000 nm. Thus, the time during which the polishing pad stays at each position is in the range of about 30 to 180 seconds.

Preferably, the retainer ring has a size such that it can support a part of the polishing pad which is protruded out of the surface to be processed when the center axis of the polishing pad reaches the periphery of the workpiece. Therefore, the width of the retainer ring (which corresponds to the distance between the outer diameter and the inner diameter of the retainer ring) is the same as or larger than the radius of the polishing pad.

When the polishing tool as shown in FIG. 3 is used, an open-cell foam is disposed in the space which is formed between the elastic member and the polishing holder. The foam is preferably an urethane foam (i.e. urethane sponge). The foam body is formed so as to correspond to the shape of the space in the polishing tool. For example, one surface of the foam may be fixed to the polishing tool by a double-faced adhesive tape and the other surface of the foam may be fixed to the elastic member by a double-faced adhesive tape. The fluid may be supplied through one inlet port to expand the foam since there is interconnection between the cells of the open-cell foam. The fluid is preferably supplied through a plurality of the inlet ports.

The method of the present invention is suitable for being applied to a process for producing the semiconductor device as explained in the chapter of “RELATED ART” comprising: forming a wiring using a proper electrically conductive material on a semiconductor wafer; forming a film of an insulating material thereupon; and thereafter polishing the insulating material. Furthermore, the present invention can be applied to an polishing process which comprises: forming trenches in a semiconductor wafer; forming an electrically conductive material film so that the trenches can be filled with the electrically conductive material; and thereafter polishing the electrically conductive material so as to remove the material except that in the trenches. Moreover, the present invention can be applied to a process for producing the semiconductor other than the above-mentioned processes, such as a planarization process comprising polishing a polysilicon film, an epitaxial film, a resist film, a metal plug or a silicon nitride film, which is formed on a semiconductor wafer.

The method of the present invention is also applied to a process for producing a liquid-crystal display panel. In the process for producing the liquid-crystal display panel, the method of the present invention is carried out to planarize a surface of a conductor layer and/or an insulating layer which is formed on a substrate of the liquid-crystal display panel.

The present method for carrying out the planarization processing is characterized in that, at two or more different positions on the surface to be processed respectively, the polishing pad is disposed above the surface to be processed, so that a part of the surface to be processed is exposed out of the shadow of the polishing pad; the surface to be processed is contacted with the polishing pad so as to generate the pressure therebetween; and the polishing pad is oscillated, while rotating the workpiece around its center axis as a rotation axis so as to polish the surface to be processed, and thereby a processed amount at each position becomes the desired one.

According to one preferable embodiment of the method for the planarization of the present invention, in a set of the residence times of the polishing pad at each position, one residence time is different from other one or more residence times, and thereby a processed amount at each position on the surface to be processed becomes the desired one. According to other embodiment of the method for the planarization of the present invention, the polishing pad is rotated around its center axis as a rotation axis, and the rotation number of the polishing pad at one position is different from the rotation number at other one or more positions, and thereby a processed amount at each position on the surface to be processed becomes the desired one.

Thus, according to the method for the planarization of the present invention, without regard to the sort of the surface to be processed, the surface to be processed can be uniformly planarized. Furthermore, according to the present invention, the residence time or the rotation number of the polishing pad at each position is determined according to the properties of the surface to be processed, and thus a planarization processing with an excellent reproducibility can be carried out.

Besides, by using the polishing tool having the open-cell foam body, even when a part of the polishing pad is protruded out of the surface to be processed, and thus the support for the part is lost, a pressure which is applied to the protruded portion of the polishing pad is not excessively increased as compared with the pressures applied to the other portions. Therefore, according to the polishing apparatus comprising such polishing tool, the present method, in which a part of the polishing pad is often exposed (or protruded) out of the surface to be processed by shifting the center axis of the polishing pad, can be conveniently carried out.

While the invention has been particularly shown in the drawings and described with reference to the preferred embodiments thereof, it will be understood by those skilled in the art that various changes in details may be made without departing from the spirit and scope of the invention.

What is claimed is:

1 A method for carrying out a planarization processing comprising polishing a surface to be processed of a workpiece with a polishing pad so as to planarize the surface to be processed, which comprises:
(a) disposing said polishing pad above said surface to be processed, so that a part of said surface to be processed is exposed out of the shadow of said polishing pad;
(b) contacting said surface to be processed with said polishing pad so as to generate a pressure therebetween; and
(c) oscillating said polishing pad while rotating said workpiece around its center axis as a rotation axis so as to polish said surface to be processed,
respectively at two or more different positions on said surface to be processed, in which method a processed amount at one position is different from that at other one or more positions on said surface to be processed.

2. The method for carrying out a planarization processing according to claim 1, wherein in a set of the residence times of said polishing pad at respective positions, one residence time is different from other one or more residence times.

3. The method for carrying out a planarization processing according to claim 1, wherein the area of an abrasive surface of said polishing pad is smaller than the area of said surface to be processed of said workpiece.

4. The method for carrying out a planarization processing according to claim 1, wherein said workpiece and said polishing pad are disc-shaped, and said polishing pad is oscillated in a radial direction of said workpiece.

5. The method for carrying out a planarization processing according to claim 4, wherein the center of said polishing pad is shifted from the center toward the periphery side of said surface to be processed in the radial direction of said surface, and thereby said polishing pad is disposed at two or more positions so that a part of said surface to be processed is exposed out of the shadow of said polishing pad and distances between the center axis of said workpiece and the center axis of said polishing pad upon being disposed at the positions are different from each other.

6. The method for carrying out a planarization processing according to claim 5, wherein when the center of said disc-shaped polishing pad is shifted “n” times (wherein “n” is an integer of 1 or more) by length “d” in the radial direction of said disc-shaped workpiece from the center to the periphery of said disc-shaped workpiece and the residence time of said polishing pad at each position is determined by:
previously determining a (n+1)×(n+1) matrix “A” of which an element “a_{ydxd}” located in the (y+1)th row and the (x+1)th column represents a polishing rate of said surface to be processed at the position which is “yd” apart from the center of said workpiece when said polishing pad is disposed at a position where the distance between the center of said polishing pad and the center of said workpiece is “xd”, wherein “x” is an integer of 0 to n;
arranging the desired processed amounts of said workpiece in a (n+1)×1 matrix “H” in which an element located in the (y+1)th row represents as “h_{yd}” the desired processed amount at the position which is “yd” apart from the center of said workpiece wherein “y” is an integer of 0 to n;
calculating the product of the inverse matrix “A⁻¹” of the matrix “A” and the matrix “H” to determine a (n+1)×1 matrix “T” in which an element located in the (x+1)th row represents as “t_{xd}” the residence time of said polishing pad at the position where the center of said polishing pad is “xd” apart from the center of said workpiece wherein “x” is an integer of 0 to n.

7. The method for carrying out a planarization processing according to any one of claims 1 to 6, wherein said polishing pad is rotated around its center axis as a rotation axis, while said polishing pad is oscillated.

8 The method for carrying out a planarization processing according to claim 7, wherein the rotation number of said polishing pad at certain one position is different from the rotation number at at least one other position.

9. The method for carrying out a planarization processing according to claim 1, wherein before a pressure between said surface to be processed and said polishing pad is generated, the oscillation of said polishing pad is started.

10. The method for carrying out a planarization processing according to claim 1, wherein a fluid is fed into a space in a polishing tool, which space is in contact with one surface of an elastic member while said polishing pad is disposed on the other surface of the elastic member, and thus a pressure of said fluid is transferred to said polishing pad through said elastic member, and thereby a pressure is applied to said surface to be processed from a side of said polishing pad so as to generate the pressure between said surface to be processed and said polishing pad.

11. The method for carrying out a planarization processing according to claim 1, wherein a fluid is fed into an open-cell foam body, which is disposed in a polishing tool to be in contact with said polishing pad with said elastic member interposed between the open-cell foam body and said polishing pad, and a pressure of said fluid is transferred to said polishing pad through said foam body and said elastic member, and thereby a pressure is applied to said surface to be processed from the side of said polishing pad so as to generate the pressure between said surface to be processed and said polishing pad.

12. The method for carrying out a planarization processing according to claim 10 or 11, wherein said fluid is a gas or a liquid.

13. The method for carrying out a planarization processing according to claim 1, wherein the planarization process is chemical-mechanical polishing or mechano-chemical polishing.

14. The method for carrying out a planarization processing according to claim 5 or 6, which is carried out in a process for producing a semiconductor device.

15. An apparatus for carrying out planarization processing, comprising a polishing tool, said polishing tool comprising a polishing pad, a polishing pad holder, an open-cell foam body which is disposed in said polishing pad holder, and an elastic member which is disposed between said polishing pad and said foam body.
